(19) United States
(12) Patent Application Publication
(10) Pub. No.: US 2019/0154758 A1
(43) Pub. Date: May 23, 2019

(54) DETERMINING AN OPERATING STATE OF AN ELECTRICAL MACHINE COUPLED TO AN INTERNAL COMBUSTION ENGINE BY MEANS OF A FREEWHEEL MECHANISM

(71) Applicant: Robert Bosch GmbH, Stuttgart (DE)

(72) Inventor: Paul Mehringer, Stuttgart (DE)

(21) Appl. No.: 16/317,681

(22) PCT Filed: Jun. 19, 2017
(86) PCT No.: PCT/EP2017/064866

§ 371 Date: Jan. 14, 2019

(30) Foreign Application Priority Data
Jul. 15, 2016 (DE) 10 2016 212 955.4

(51) Int. Cl. G01R 31/34

(52) U.S. Cl. CPC G01R 31/343

(57) ABSTRACT

The invention relates to a method for determining an operating state (B) of an electric machine (114) which is coupled to an internal combustion engine (112) by means of a freewheel mechanism (111), having the steps: determining a time profile of a rotational speed (N) of the electric machine (114) and determining at least one freewheeling phase (PH_{FL}) of the electric machine (114) from the rotational speed (n) and the falling rotational speed edge (126b) which is assigned to the freewheeling phase (PH_{FL}), wherein the operating state B of the electric machine (114) is inferred if the rotational speed edge (126b) has a profile shape which deviates from a standard profile (126c). Furthermore, the invention relates to a corresponding computing unit which is configured, by means of corresponding storage means and a computer program, to carry out the method according to the invention, and to a corresponding computer program.

### BACKGROUND OF THE INVENTION

The present invention relates to a method for determining an operating state of an electric machine, which is coupled to an internal combustion engine by means of a freewheel mechanism, as well as a computing unit, preferably a controller, for an electric machine, and a computer program for carrying out the method.

Electric machines, in particular externally excited electric machines, can be used to control the onboard-supply voltage in vehicles.

These electric machines have a controller, which controls the exciter current of the electric machine depending on the onboard electrical system voltage of the vehicle. The electric machine is coupled to the internal combustion engine, by means of a coupling element, typically a belt drive, wherein the coupling element is subjected to different torques or braking torques both from the internal combustion engine and also from the electric machine. In order to protect the belt, the electric machine can have a freewheeling element in order to reduce the abrasion of the belt drive brought about by the torque application of the electric machine or the internal combustion engine.

The electric machine can therefore have freewheeling phases, in which the freewheeling element is active and therefore the electric machine is decoupled from the internal combustion engine. The freewheeling element is in particular active when the rotational speed of the electric machine is greater than that of the internal combustion engine.

The determination of such freewheeling phases within an electric machine is disclosed, for example, in the still unpublished applications DE 10 2016 201 958, DE 10 2016 201 960 or DE 10 2016 208 704, wherein the methods presented there for determining the respective freewheeling phases are intended to become the subject matter of this application in their full scope by explicit reference.

As a result of the decoupling of the electric machine from the internal combustion engine within the freewheeling phases, the electric machine responds within these freewheeling phases very sensitively to any influence, which may change the rotational speed of the electric machine.

If there is generally hereinafter talk of an electric machine, this can also comprise here a generator- and/or motor-operatable electric machine.

In principle, it would therefore be desirable to use the sensitive time interval of the rotational speed profile within the freewheeling phases of the electric machine to obtain any operating states of the electric machine, the internal combustion engine or the onboard electrical system to which the electric machine is typically coupled, by means of an analysis of machine parameters of the electric machine within the time interval of the freewheeling phases of the electric machine.

### SUMMARY OF THE INVENTION

A method for determining an operating state of an electric machine coupled to an internal combustion engine by means of a freewheel mechanism as well as a computing unit and a computer program for carrying out the method according to the invention are proposed.

The method is used to determine an operating state of an electric machine coupled to an internal combustion engine by means of a freewheel mechanism. The operating states of the electric machine to be determined preferably comprise the state of a malfunction of a rectifier of the electric machine, in particular an active rectifier, and/or a load application of the electric machine, which can be obtained, for example, by switching on and/or switching off a consumer in the onboard electrical system and the load resulting from this.

It has been identified that a determination of such operating states can in particular then be determined particularly simply and reliably and with a reliable result by means of the measured quantities provided in an electric machine when the electric machine is decoupled from the internal combustion engine driving it. In the case of an electric machine with a belt pulley coupled onto the electric machine by means of a freewheeling element, this is particularly the case when the freewheeling element is active, i.e. when the rotational speed of the belt pulley forcibly coupled to the internal combustion engine is lower than the rotational speed of the electric machine or of the rotor of the electric machine.

The respective operating states of the electric machine are obtained by the characteristic profile shape of the time profile of the rotational speed in the time interval of the active freewheeling, i.e. during a freewheeling phase of the electric machine, wherein in a first step, a time profile of a rotational speed of the electric machine is determined, at least one freewheeling phase of the electric machine is determined from this time profile of the rotational speed, and from the at least one rotational speed edge assigned to the freewheeling phase, the respective operating state of the electric machine is then inferred by means of a comparison of the profile shape of the respective rotational speed edge and a standard profile.

A corresponding standard profile comprises a typical profile shape of the rotational speed for the respective operating state of the electric machine in the time interval of a freewheeling phase, wherein the respective standard profile depends on parameters of the electric machine such as, for example, the absolute rotational speed of the electric machine.

The respective standard profiles, which can be assigned to the respective operating states, can be stored on a storage means, preferably in a computing unit of the electric machine, in particular a controller, with the result that the operating state recognition of the electric machine can be performed in an advantageous manner autonomously in the electric machine itself, without a controller arranged externally to the electric machine being absolutely and imperatively essential for this. In addition, it is understood that such a determination can also be performed alternatively or cumulatively in a controller located externally to the electric machine, for example a motor controller in a motor vehicle, in order, for example, to bring about a redundant determination of the operating state.

In addition, it is understood that the determination of the freewheeling phases can be determined by evaluating the time variation of the rotational speed of the electric machine at least in the time interval of a decreasing edge of an oscillating rotational speed oscillation of the electric machine brought about by the internal combustion engine and/or an introduction of a specific load application of the electric machine and inferring the presence of a freewheeling phase from the load application. Such methods for determining freewheeling phases are, as already mentioned initially, disclosed in the applications DE 10 2016 201 958, DE 10 2016 201 960 or DE 10 2016 208 704, wherein the methods disclosed in these documents for determining freewheeling phases of an electric machine are intended to be the subject matter of this application by explicit reference to the respective methods disclosed there.

In a preferred embodiment of the invention, the time profile of at least one phase signal of the electric machine coupled to the internal combustion engine is determined, wherein the time profile of the rotational speed of the electric machine is determined from the phase signal.

Such an embodiment is advantageous since the rotational speed or the time profile of the rotational speed and from this the freewheeling phases of the electric machine and the respective operating states of the electric machine can be determined directly from measured quantities provided in the electric machine in the form of a phase signal. Thus, a further sensor for determining the rotational speed of the electric machine is not absolutely necessary, with the result that in particular costs can be saved. The phase signal of the electric machine here comprises in particular at least one of the phase voltages and/or at least one of the phase currents of the electric machine.

Furthermore, a determination of the rotational speed from a plurality of phase signals can be advantageous in order to increase the accuracy of the rotational speed determination and the reliable provision of the rotational speed signal. This is particularly advantageous when the profile shape of the rotational speed edge has deviations from the standard profile of the rotational speed edge, in particular has periodic deviations from the standard profile, whose time characteristic is of the same order of magnitude as the signal of a phase signal scanning the rotational speed profile, in particular a phase voltage. The phase signals typically comprise pulses having ascending and descending edges. By using both the ascending and also descending edges of at least one phase signal and/or using the respective edges of a plurality of phase signals, the time resolution of the rotational speed scanning can thus be significantly increased and a reliable determination of the operating state of the electric machine can thereby be ensured.

In a further preferred embodiment of the invention, the time profile of the rotational speed of the electric machine can be determined alternatively or cumulatively by means of a rotational speed sensor. In particular, by means of a cumulative use of the rotational speed sensor, a redundant determination of the rotational speed of the electric machine is possible. Such a rotational speed sensor, which can be attached to the electric machine or arranged in the electric machine to determine the rotational speed, can, for example, comprise an inductive, capacitive or optical sensor, which preferably transmits the rotational speed signal to the computing unit of the electric machine but can also cumulatively or alternatively transmit to a controller arranged externally to the electric machine, e.g. a motor controller.

In a further preferred embodiment of the invention, the standard profile of the rotational speed edge has a strictly monotonically decreasing profile of the rotational speed. As a result of this strictly monotonically decreasing profile of the rotational speed, in particular in a time interval, which approximately corresponds to half an oscillation period of the oscillations brought about by the internal combustion engine in the rotational speed profile of the electric machine, a reliably detectable time window of a freewheeling phase is obtained, which can be used to determine the operating states of the electric machine. Preferably the standard profile of the rotational speed edge has a substantially linear profile, wherein depending on the operating state to be determined for such a linear or strictly monotonically decreasing profile of the rotational speed, corresponding acceptance values of a slope can be predefined, which are assigned to the respective operating state of the electric machine.

By this means, the rotational speed profile in the time interval of a freewheeling phase can be compared with the standard profile of the rotational speed edge to be expected in a particularly simple and reliable manner and from this comparison the respective operating state of the electric machine can be inferred reliably and reproducibly.

In a further preferred embodiment of the invention, a malfunction of the rectifier of the electric machine is inferred if the profile shape of the rotational speed edge has a rotational speed oscillation superimposed on the standard profile, wherein the malfunction is preferably accomplished by determining an amplitude and/or frequency of the rotational speed oscillation in the time range of the rotational speed edge.

A malfunction of the rectifier preferably comprises a functional impairment of at least one of the rectifying elements of a rectifier or the total failure of at least one of these elements. The rectifying elements can comprise passive rectifying elements such as, for example, diodes and/or active elements such as, for example transistors in particular MOSFET transistors, which are controlled by means of a controller of the electric machine. A malfunction of at least one rectifying element of the rectifier results in a rotational speed oscillation, which is also designated as ripple, wherein such ripples are superimposed on the rotational speed signal of the electric machine. Such ripples can readily be detected only in a decoupled state of the electric machine from the internal combustion engine, since such ripples are correspondingly smoothed by the internal combustion engine driving the electric machine. Thus, these ripples can be detected particularly readily in the descending edge within a freewheeling phase.

By determining the amplitude and/or the frequency, not only the presence of such a defect but also the degree of damage to the respective rectifier element or the respective rectifier elements and the number of possibly affected rectifier elements can be inferred. The rotational speed oscillation or ripple brought about by the malfunction typically exhibits a proportionality to the rotational speed of the electric machine, wherein the proportionality is given in dependence on the number of phases of the electric machine or the rectifier elements assigned to the phases of the electric machine, which are possibly damaged. This rotational speed oscillation has a higher frequency compared to the rotational speed oscillation brought about by the internal combustion engine and should therefore be readily distinguished from this.

In a further preferred embodiment of the invention, a load application of the electric machine is inferred if a profile shape of the rotational speed edge is determined, which has a strictly monotonic profile with a gradient of the slope which is changed compared with the standard profile. The deviation of the gradient of the rotational speed edge from the standard profile is typically significantly enlarged in such a manner that it can be readily determined from the rotational speed signal. In the case of a constant load application of the electric machine, typically a substantially linear behavior of the rotational speed time profile within the rotational speed edge can be expected in the freewheeling phase, wherein in the case of the load application, merely the slope of the rotational speed edge increases significantly. In the case of a pulsed load application of the electric machine, a pulsed variation of the gradient of the descending rotational speed edge corresponding to the pulsed application is obtained within the freewheeling phase. Here in particular the temporal extension of the pulse and its amplitude is relevant.

In a further preferred embodiment of the invention, a malfunction of the rectifier is inferred if the profile shape of the rotational speed edge within a time interval exceeds and/or falls below at least one threshold value, preferably substantially periodically exceeds and/or falls below the threshold value within the time interval.

By means of a threshold value comparison, a profile of the rotational speed edge which deviates from a standard profile can be determined particularly simply. Depending on the operating state to be determined, i.e. in particular defects of the rectifier or load application of the electric machine, a corresponding threshold value can be stored for interrogation, for example in the computing unit of the electric machine, preferably in a storage device. Since in the case of a load application of the electric machine by means of a pulsed load, the time profile shape of a rotational speed edge has a characteristic profile similar to the respective load application, the criterion of a periodic profile of the rotational speed edge can be used in particular as a distinguishing criterion between a load application and a malfunction of a rectifier since typically such load applications do not have a periodic profile or have a different frequency signature compared with a rectifier error.

In a further preferred embodiment of the invention, in particular a load application of the electric machine is inferred if the profile shape of the rotational speed edge within a time interval exceeds and/or falls below at least one threshold value of a gradient of the standard profile. Since the profile shape of the rotational speed edge has a profile proportional to the respective load application, such a load application can be determined very reliably by means of a threshold value comparison of a gradient. Such threshold value gradients can either be stored in the computing unit of the electric machine and/or in an external controller in order to determine such operating states.

Further advantages are obtained in using a computer program stored on a machine-readable storage medium, which causes a computing unit to carry out a method according to the previous implementations when it is executed on the computing unit.

A further advantageous embodiment of the invention is manifest in the computing unit, in particular a controller for an electric machine, which is set up to carry out a method according to the preceding implementations by means of the computer program provided on the computing unit, in particular on a storage medium of the computing unit, and/or by means of a corresponding integrated circuit. This results in synergies since the computing unit, in particular the controller, is not only used for controlling the electric machine but is also set up for carrying out the method according to the invention.

Further advantages and embodiments of the invention are obtained from the description and the appended drawings.

### BRIEF DESCRIPTION OF THE DRAWINGS

FIG. 1 shows an electric machine coupled to an internal combustion engine by means of a freewheeling element in a schematic view;

FIG. 2 shows a schematic view of a method for determining an operating state of an electric machine;

FIG. 3 shows a schematic view of phase windings of an electric machine connected in a star shape and the rectifier elements arranged on the stator phases of the electric machine;

FIG. 4 shows a time profile of a phase voltage, the rotational speed of an electric machine derived from this at some time points, and the average rotational speed within a time interval;

FIG. 5a shows a comparison of the rotational speed profile of a belt pulley (dashed line) coupled to an electric machine by means of a freewheel mechanism and the rotational speed profile of the electric machine when the freewheel mechanism is active within freewheeling phases;

FIG. 5b shows a standard profile of the rotational speed of the electric machine within a time interval (shown by the dashed line) and an actual profile of the rotational speed of the electric machine in the case of a defect in the rectifier of the electric machine (continuous line); and

FIG. 6 shows the rotational speed profile in the case of a load application of the electric machine.

### DETAILED DESCRIPTION

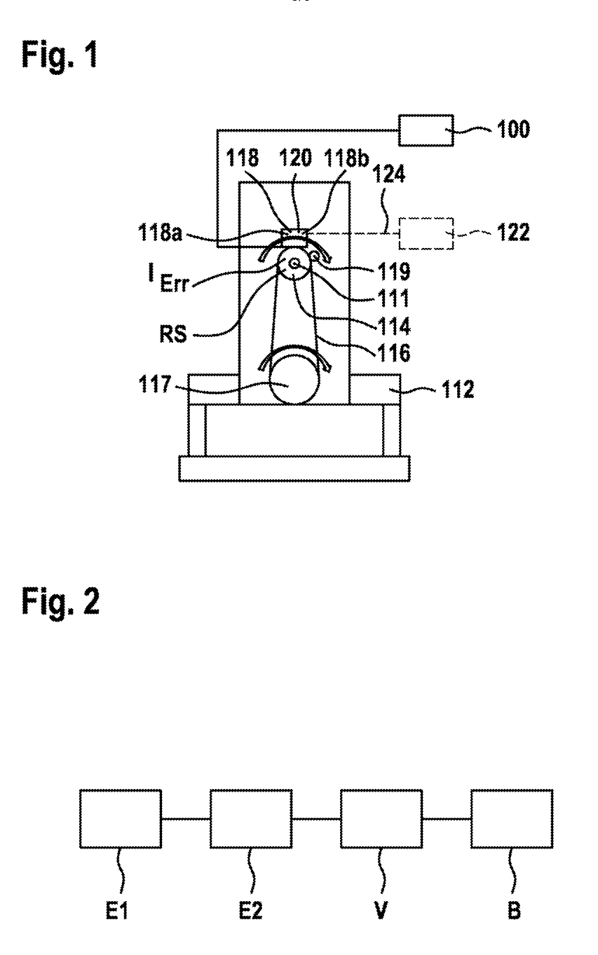

FIG. 1 shows a method (cf. FIG. 2) for determining an operating state of an electric machine 114 coupled to an internal combustion engine 112 by means of a freewheel mechanism 111, which electric machine is driven by the internal combustion engine 112 by means of a coupling element 116 acting on a belt pulley RS of the electric machine 114.

The coupling element 116 is operatively connected to the crankshaft 117 of the internal combustion engine 112 on the motor side. The internal combustion engine 112 delivers the torque in a pulsed manner to the crankshaft 117 by way of the work cycles of the respective cylinder of the internal combustion engine 112. The pulse-like torque delivery of the internal combustion engine 112 is typically accompanied by an abrasion of the coupling element 116, which is alleviated by the freewheeling element 111 provided on the electric machine. In order to control the voltage in the onboard electrical system 100, a computing unit 118 in the form of a controller 120 is provided, which regulates the exciter current IErr of the electric machine 114 accordingly depending on the voltage of the onboard electrical system 100.

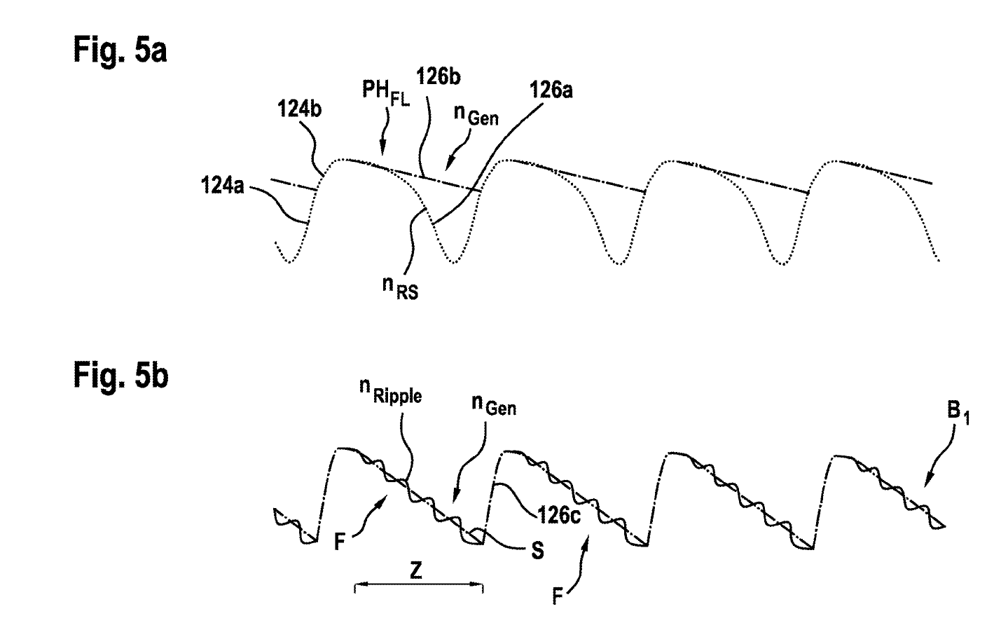

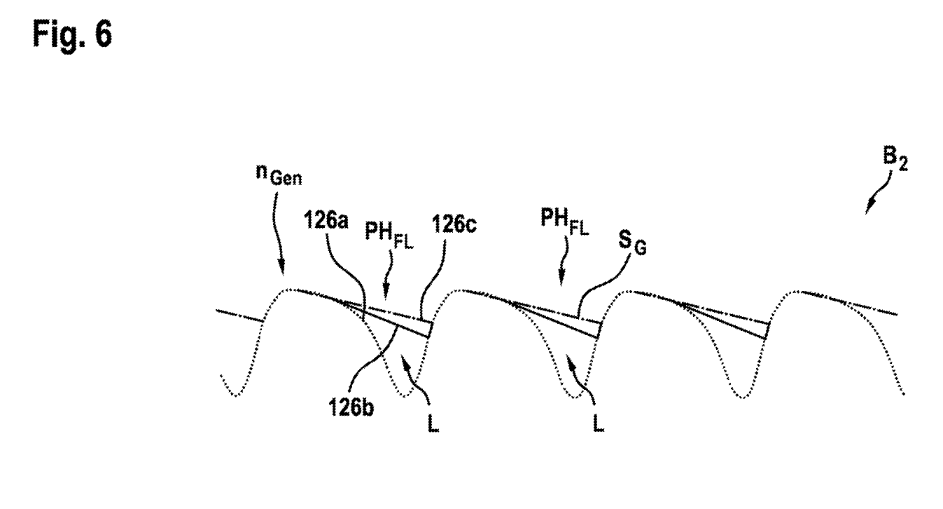

In order to be able to determine the operating states B of the electric machine 114 based on physical state variables, which can be determined in the electric machine 114, it is advantageous if the electric machine 114 is decoupled from the internal combustion engine 112. The respective operating states B in particular comprise the operating state malfunction F of a rectifier 106 (cf. FIG. 5) and/or load application L of the electric machine 114 (cf FIG. 6). These aforesaid operating states B have an influence on the rotational speed profile n_{Gen} of the electric machine 114, wherein the component influencing the time profile of the rotational speed n_{Gen} can only be determined in the time interval in which the electric machine 114 is decoupled from the internal combustion engine 112. This is because as a result of the forced coupling between internal combustion engine 112 and electric machine 114, the variation of the rotational speed profile n_{Gen} of the electric machine 114 caused by the respective operating states B is smoothed as far as possible by the coupled-on masses of the internal combustion engine 112 and thus cannot be determined in the rotational speed profile n_{Gen}.

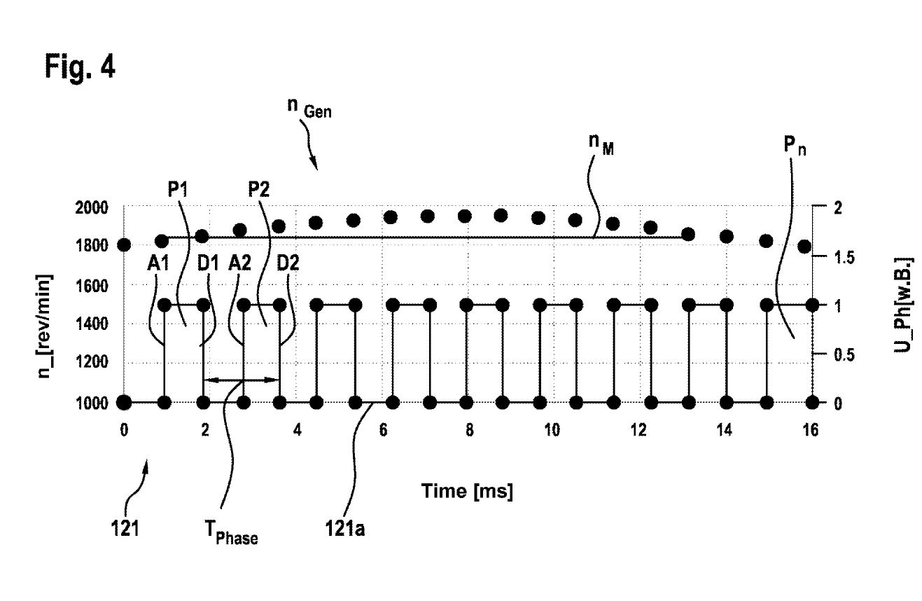

The precise knowledge of freewheeling phases PH_{FL} of the electric machine 114 is thus of decisive importance for determining operating states since by this means the respective operating states of the electric machine can be determined particularly simply and reproducibly. The freewheeling phases PH_{FL} can thus be determined by means of the characteristic torque profile for the freewheeling phases PH_{FL}, which is typically localized in time in the range of the descending rotational speed edges of the rotational speed ripple brought about by the internal combustion engine 112 in the rotational speed of the electric machine 114. The rotational speed time profile n_{Gen} of the electric machine 114 is determined by a phase signal 121 of the electric machine (cf on this matter FIG. 4). In addition, a rotational speed sensor 119 can be arranged on the electric machine, which sensor is set up to determine the rotational speed n_{Gen} of the electric machine 114 and to transmit the rotational speed to the computing unit 118. For controlling and for executing the method (cf. FIG. 2) the computing unit 118 has a storage device 118a and/or a computing architecture 118b suitable for regulating and for executing the method, wherein a computer program can be stored on the storage device 118a. In addition, the computing unit can cumulatively or alternatively also have an integrated circuit for carrying out the method set up accordingly on the hardware side.

A communications link 124 can also be provided (shown by the dashed lines) for recording and transmitting data using a motor control unit 122.

The computing unit 118, in particular the controller 120, can additionally be provided for carrying out the method described hereinafter for determining the operating states B of the electric machine 114. In step E1 the time profile of the rotational speed n_{Gen} of the electric machine 114 is determined. As already mentioned initially, the determination of the rotational speed n_{Gen} of the electric machine 114 can either be determined by means of the phase signal 121 (cf. FIG. 4) or by means of a plurality of phase signals and/or by means of a rotational speed sensor 119 (cf. FIG. 1). In step E2 a freewheeling phase PH_{FL} of the electric machine 114 is determined from the rotational speed n_{Gen} and the descending rotational speed edge 126b assigned to the freewheeling phase PH_{FL} (cf. FIGS. 5 and 6). In a further step V the rotational speed profile in the time interval of the rotational speed edge 126b is compared with a standard profile 126c of a rotational speed edge, wherein the respective standard profile is assigned to a respective operating state B1 malfunction F of a rectifier 107 or B₂ load application L of the electric machine 114. By means of the deviation of the rotational speed edge 126b determined from the rotational speed n_{Gen} from the respective standard profile 126c of the rotational speed edge, which is assigned to a respective operating state B, the respective operating state of the electric machine 114 is inferred in a further process step B.

It is understood that in addition to the aforesaid operating states, further operating states of the electric machine can also be determined on the basis of the previously described method, which operating states have a characteristic effect on the rotational speed profile n_{Gen} of the electric machine 114. This also includes operating states, in which, for example, due to mechanical wear effects such as, for example, degradation of the bearings or of the other mechanical components of the electric machine (not shown), the rotational speed profile of the electric machine 114 varies characteristically.

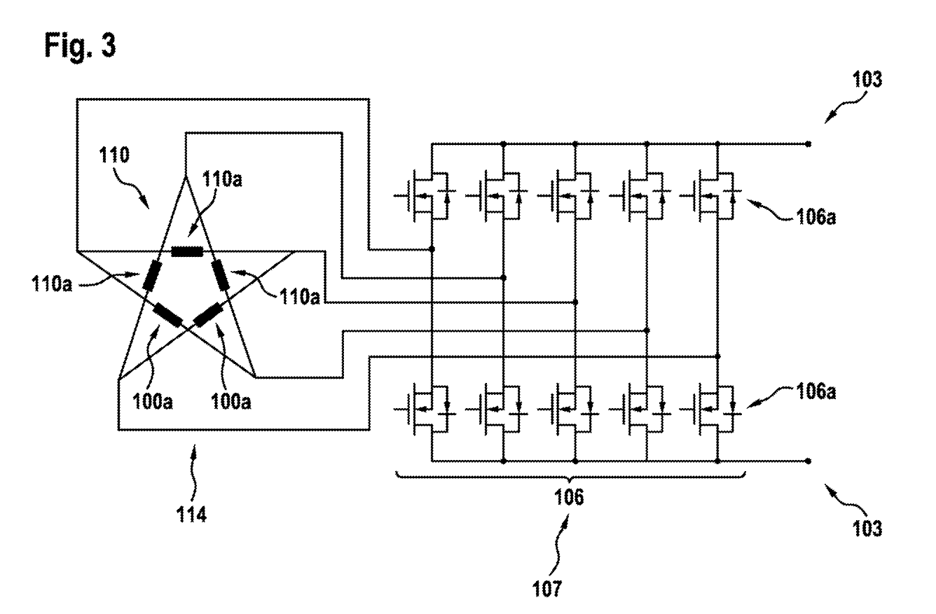

FIG. 3 shows the electric machine 114 in the manner of a circuit diagram. In this example, the electric machine 114 is shown as an example as a five-phase electric machine 114. The electric machine 114 has a stator 110 with a five-phase stator winding 110a. The converter 106 comprises a plurality of electrical switching elements, which in this example are configured as MOSFETs 106a (metal-oxide-semiconductor field effect transistors). MOSFETs correspond in circuit technology to a transistor and an inverse diode switched in the reverse-biased direction. The MOSFETs 106a are, for example, connected on the one hand via busbars to the stator windings 110a and on the other hand to the DC voltage terminals 103.

The converter 106 can be operated in the generator mode of the electric machine 114 as rectifier 107.

In the generator mode of the electric machine 114, a five-phase alternating voltage, the so-called phase voltage, is generated in the stator winding 110a. By means of expedient clocked control of the MOSFETs 106a by the controller 120, this five-phase alternating voltage is converted into a DC voltage. By means of this converted DC voltage, the onboard electrical system 122 is supplied with energy.

The determination of the rotational speed signal n_{Gen} from the phase signal 121 of the electric machine 114 is described in more detail in FIG. 4. The rotational speed n_{Gen} of the generator in revolutions per minute is plotted on the left-hand ordinate of FIG. 4, the phase voltage in arbitrary units is plotted on the right-hand ordinate and the time in milliseconds (ms) is plotted on the abscissa of the diagram. These details merely have an explanatory character and are not intended to restrict the invention to the specified ranges. In addition, the specified ranges are fundamentally correspondingly scalable.

The phase signal 121 predominantly comprises one of the phase voltages 121a of the stator-side phases 110a of the electric machine 114. It is understood that any arbitrary phase voltage of one or more phases 110a of the electric machine 114 can fundamentally be used for this purpose but the respective phase currents can also be used to determine the rotational speed signal n_{Gen} of the electric machine 114 from this. In principle, when using more than one phase voltage, a correspondingly higher time resolution of the rotational speed signal n_{Gen} can be achieved (not shown).

In a generator with current delivery the phase voltage 121a runs rectangularly to a first approximation. Thus, the phase voltage 121a has pulses P₁, P₂ . . . Pₙ, wherein an average phase time or pulse width T_{Phase} can be recorded between directly adjacent pulses P, which average phase time or phase width are typically determined on the respectively ascending A1, A2 or descending D1, D2 edges of the pulses P₁, P₂ . . . Pₙ. It is understood that by determining the phase time T_{Phase} both by using the ascending A1, A2 and the descending D1, D2 edges of the pulses P, the resolution of the rotational speed n_{Gen} can be increased accordingly. The rotational speed n_{Gen} of the electric machine 114 is accordingly obtained from the formula:

n_{Gen}=60/(T_{Phase}*PPZ),

wherein n_{Gen} is the rotational speed of the electric machine 114 in revolutions per minute and PPZ is the pole pair number of the electric machine.

The rotational speed n_{Gen} determined in each case by means of the phase pulses P is shown as a temporally offset arrangement of individual points and the average rotational speed n_{M} within the time interval is shown as a continuous line inside the diagram.

The rotational speed can preferably be determined digitally. By means of a measurement of the temporal spacings T_{Phase} of the amplitudes in the phase signal 121 of the electric machine 114, as already described, the instantaneous rotational speed n_{Gen} and when the freewheel mechanism 111 is inactive, the rotational speed of the crankshaft 117 as well can be determined directly. If parameters such as number of cylinders, transmission ratio and pole pair number PPZ of the electric machine 114 are known in the recorded time interval, the controller 118 can store a fixed number of rotational speed values in a storage device, for example, in a shift register (not shown), and determine a maximum and a minimum instantaneous rotational speed in each case at least within an oscillation cycle. The maximum and minimum instantaneous rotational speeds preferably comprise the peak rotational speeds (local minima and/or maxima) in the respectively recorded time range. The difference between these rotational speeds is a measure for the rotational speed oscillation brought about by the internal combustion engine 112 and thus for the delivered torque. As already explained, a plurality of cycles of the rotational speed oscillation can also be recorded for a yet more precise determination of the rotational speed.

FIG. 5a shows the rotational speed profile n_{RS} of the belt pulley (dotted profile) and the rotational speed n_{Gen} of the electric machine 114 (continuous line). The belt pulley RS is always forcibly coupled to the crankshaft 117 of the internal combustion engine 112 via the coupling element 116, with the result that the rotational speed oscillation already described initially, which is transmitted by the internal combustion engine 112 to the belt pulley, is clearly distinguished in the rotational speed profile n_{RS}. The electric machine 114 has freewheeling phases PH_{FL}, in which the electric machine 114 is decoupled from the internal combustion engine 112. These freewheeling phases PH_{FL} occur in the region of the descending edges 126a, 126b of the rotational speed n_{RS} of the belt pulley RS or the rotational speed n_{Gen} of the electric machine 114. In the ascending edges 124a, b of the rotational speed n_{RS} of the belt pulley RS or of the rotational speed n_{Gen} of the electric machine 114, the electric machine 114 is accordingly driven by the internal combustion engine 112.

FIG. 5b shows the rotational speed profile n_{Gen} of the electric machine 114 in enlarged view compared with FIG. 5a (continuous line). This rotational speed profile is superimposed on a standard profile 126c (dashed line), wherein the standard profile 126c is assigned to the operating state B₁ of the electric machine 114 associated with a malfunction F of the rectifier 107. In the region of the descending edge 126b of the rotational speed n_{Gen} of the electric machine 114, a rotational speed oscillation n_{Ripple} is superimposed which is of a high frequency in comparison with the rotational speed oscillation imparted by the internal combustion engine (cf. FIG. 5a). This rotational speed oscillation n_{Ripple}, which is associated with a malfunction F of the rectifier 107, can be extracted by comparison with the standard profile 126c and the operating state B1 can be derived from this. A determination of the rotational speed oscillation n_{Ripple} can either be made by subtracting the standard profile 126c from the generator rotational speed or the standard profile 126c can be used as threshold value profile S and a malfunction F of the rectifier can then be inferred if the rotational speed n_{Gen} of the electric machine exceeds or falls below the threshold value S in particular in the time range of the freewheeling phases PH_{FL}. In addition, the characteristic amplitude of the rotational speed oscillation n_{Ripple} superimposed in the time range of a freewheeling phase PH_{FL} or the frequency of this rotational speed oscillation can otherwise be used to diagnose a malfunction F of the rectifier and in addition, the type, extent and temporal progress of the given damage to the rectifier 107 as well as the number of elements of the rectifier 107 affected by the malfunction F can be inferred from the frequency and amplitude of the rotational speed oscillation n_{Ripple}.

FIG. 6 shows a second operating state B₂ of the electric machine 114, which is associated with a load application L of the electric machine 114. The load application L is, as shown in FIG. 6a, substantially constant in time. The load application can, however, also have a different temporal profile shape (not shown), wherein the respective load application L (cf. FIG. 6) is reflected as a characteristic signature of the rotational speed n_{Gen} of the electric machine in the range of the freewheeling phases PH_{FL}. As is also already explained in FIG. 5, the operating state B₂ is determined in the form of a load application L of the electric machine by comparison of the rotational speed edge 126b in the time range of a freewheeling state PH_{FL} with a corresponding standard profile 126c of the rotational speed edge. Here also the comparison can be made by subtracting the standard profile 126c from the descending rotational speed edge 126b of the generator rotational speed n_{Gen} of the electric machine 114, or the standard profile 126c can be used as a threshold value S_{G} of a rotational speed increase, from the deviation which a corresponding load application L of the electric machine 114 can be inferred. In order, for example, to distinguish an operating state B₁ (cf. FIG. 5) from an operating state B₂ (cf. FIG. 6), the typical periodicity of the rotational speed oscillation for a malfunction F in the operating state B1 can be used as a further criterion (cf. FIG. 5). The determination of the operating states is made in a time interval Z, which at least partially corresponds to a freewheeling phase PH_{FL} of the electric machine 114.

1. A method for determining an operating state (B) of an electric machine (114) coupled to an internal combustion engine (112) by means of a freewheel mechanism (111), the method comprising:
a) determining, via a computer, a time profile of a rotational speed (n) of the electric machine (114);
b) determining, via the computer, at least one freewheeling phase (Ph_{Fl}) of the electric machine (114) from the rotational speed (n) and the falling rotational speed edge (126b) assigned to the freewheeling phase (Ph_{Fl}), wherein the operating state (B) of the electric machine (114) is then inferred if the rotational speed edge (126b) has a profile shape which deviates from a standard profile (126c).

2. The method as claimed in claim 1, wherein the operating state of the electric machine (114) comprises malfunction (F) of a rectifier (107) of the electric machine (114) or load application (L) of the electric machine (114).

3. The method as claimed in claim 1, wherein the time profile of at least one phase signal (121) of the electric machine (114) coupled to the internal combustion engine (112) is determined and the time profile of the rotational speed (n) of the electric machine (114) is determined from the phase signal (121).

4. The method as claimed in claim 1, wherein the time profile of the rotational speed (n) of the electric machine (114) is determined by means of a rotational speed sensor (S).

5. The method as claimed in claim 1, wherein the standard profile (126c) of the rotational speed edge (126b) has a monotonically decreasing profile of the rotational speed (n).

6. The method as claimed in claim 2, wherein a malfunction (F) of the rectifier (107) is inferred if the profile shape of the rotational speed edge (126b) has a rotational speed oscillation (n_{Ripple}) superimposed on the standard profile (126c).

7. The method as claimed in claim 2, wherein the load application (L) of the electric machine (114) is inferred if a profile shape of the rotational speed edge (126b) is determined, which has a monotonic profile with a gradient of the slope which is changed compared with the standard profile (126c).

8. The method as claimed in claim 2, wherein the malfunction (F) of the rectifier (107) is inferred if the profile shape of the rotational speed edge (126b) within a time interval (Z) passes at least one threshold value (S).

9. The method as claimed in claim 2, wherein the load application (L) of the electric machine (114) is inferred if the profile shape of the rotational speed edge (126d) within a time interval (Z) passes at least one threshold value (S_{G}) of a gradient of the standard profile (126c).

10. A computer (118) for controlling an electric machine (114), the computer configured to:
a) determine a time profile of a rotational speed (n) of the electric machine (114);
b) determine at least one freewheeling phase (Ph_{Fl}) of the electric machine (114) from the rotational speed (n) and the falling rotational speed edge (126b) assigned to the freewheeling phase (Ph_{Fl}), wherein the operating state (B) of the electric machine (114) is then inferred if the rotational speed edge (126b) has a profile shape which deviates from a standard profile (126c).

11. (canceled)

12. A machine-readable storage medium with a computer program that when executed by the computer causes the computer to
a) determine a time profile of a rotational speed (n) of the electric machine (114);
b) determine at least one freewheeling phase (Ph_{Fl}) of the electric machine (114) from the rotational speed (n) and the falling rotational speed edge (126b) assigned to the freewheeling phase (Ph_{Fl}), wherein the operating state (B) of the electric machine (114) is then inferred if the rotational speed edge (126b) has a profile shape which deviates from a standard profile (126c).
